(19) United States
(12) Patent Application Publication
(10) Pub. No.: US 2020/0216944 A1
(43) Pub. Date: Jul. 9, 2020

(54) MASK ASSEMBLY

(71) Applicant: Samsung Display Co., Ltd., Yongin-si (KR)

(72) Inventor: Jiyun CHUN, Yongin-si (KR)

(21) Appl. No.: 16/659,942

(22) Filed: Oct. 22, 2019

(30) Foreign Application Priority Data
Jan. 7, 2019 (KR) 10-2019-0001874

(51) Int. Cl. C23C 14/04; C23C 14/06; C23C 14/24; H01L 51/00; H01L 51/56

(52) U.S. Cl. CPC C23C 14/042; C23C 14/06; C23C 14/24; H01L 27/3244; H01L 51/56; H01L 2251/53; H01L 51/0011

(57) ABSTRACT

A mask assembly includes: a mask frame having an opening; a mask on the mask frame; and a support stick between the mask frame and the mask, the support stick comprising a short side extending in a first direction and a long side extending in a second direction crossing the first direction, wherein the mask has a non-active area overlapping the support stick on a plane and an active area different from the non-active area, and the support stick contains 34 wt % to 36 wt % of nickel, 12 wt % to 15 wt % of chromium, and iron with respect to a total weight thereof.

### CROSS-REFERENCE TO RELATED APPLICATIONS

This application claims priority to and the benefit of Korean Patent Application No. 10-2019-0001874, filed on Jan. 7, 2019, the entire contents of which are hereby incorporated by reference.

### BACKGROUND

A display device may include a plurality of pixels. The plurality of pixels may form a display area after being formed through a deposition process using a deposition material. For example, an organic material may be deposited on a substrate by using a fine metal mask FMM to form a thin film having a desired pattern.

A support stick may be positioned between a mask assembly and a mask to form a non-deposition area on which the deposition material is not deposited. Some example embodiments may enable preventing a mask from being lifted or deformed during the deposition process.

The above information disclosed in this Background section is only for enhancement of understanding of the background and therefore it may contain information that does not constitute prior art.

### SUMMARY

Aspects of some example embodiments of the present disclosure may include a mask assembly that is capable of precisely depositing a deposition material.

Some example embodiments of the inventive concept may include a mask assembly including a mask frame, a mask, and a support stick. An opening may be defined in the mask frame. The mask may be located on the mask frame. The support stick may be located between the mask frame and the mask and include a short side extending in a first direction and a long side extending in a second direction crossing the first direction.

The mask may have a non-active area overlapping the support stick on a plane and an active area different from the non-active area. The support stick may contain about 34 wt % to about 36 wt % of nickel, about 12 wt % to about 15 wt % of chromium, and iron with respect to a total weight thereof.

According to some example embodiments, the support stick may further contain 10 wt % or less of at least one of manganese, cobalt, tungsten, or silicon with respect to the total weight thereof. According to some example embodiments, the support stick may have a thermal expansion coefficient of about 10 ppm/° C. 10⁻⁶ or less. According to some example embodiments, the support stick may have relative permeability of about 2,000 to about 10,000. According to some example embodiments, the support stick may have a thickness of about 50 um to about 150 um in a third direction perpendicular to a plane defined by the first direction and the second direction. According to some example embodiments, the mask may contain invar. According to some example embodiments t, relative permeability of the support stick may be about 0.5 times of that of the mask.

According to some example embodiments, a plurality of pattern holes constantly arranged at predetermined intervals may be defined in the active area of the mask. According to some example embodiments, the number of pattern holes may be equal to or greater than 640,000 per square inch of the mask.

According to some example embodiments, the support stick may include: a top surface defined by the long side and the short side; a bottom surface facing the top surface; a first side surface located between the top surface and the bottom surface to connect the top surface to the bottom surface; and a second side surface facing the first side surface. According to some example embodiments, at least one of the first side surface or the second side surface may overlap the non-active area on the plane, and a plurality of protrusion patterns protruding from the first side surface or the second side surface may be defined on at least one of the first side surface or the second side surface.

According to some example embodiments, the protrusion patterns may extend from the first side surface and the second side surface. According to some example embodiments, the protrusion patterns may include first protrusion patterns protruding from the first side surface and second protrusion patterns protruding from the second side surface. According to some example embodiments, the first protrusion patterns and the second protrusion patterns may one-to-one correspond to each other.

According to some example embodiments, the mask assembly may further include a magnetic plate located on the mask to generate magnetism.

According to some example embodiments of the inventive concept, a mask assembly may include a mask frame, a plurality of support sticks, and a plurality of masks. An opening may be defined in the mask frame. The plurality of support sticks may be located on the mask frame, be spaced apart from each other in a first direction, and include a long side and a short side. The masks may be located on the support sticks. Each of the masks may have a non-active area overlapping the support stick on a plane and an active area that is an area except for the non-active area.

Each of the support sticks may include a top surface, a bottom surface, a first side surface, and a second side surface. The top surface may be defined by the long side and the short side. The bottom surface may be a surface facing the top surface. The first side surface may be located between the top surface and the bottom surface to connect the top surface to the bottom surface. The second side surface may be a surface facing the first side surface.

According to some example embodiments, at least one of the first side surface or the second side surface may overlap the non-active area on the plane, and a plurality of protrusion patterns protruding from the first side surface or the second side surface may be defined on at least one of the first side surface or the second side surface.

The support stick may have a thermal expansion coefficient of about 10 ppm/° C. 10⁻⁶ or less. The support stick may have relative permeability that is about 0.5 times of that of the mask. According to some example embodiments, each of the support stick may have relative permeability of about 2,000 to about 10,000.

According to some example embodiments, each of the support sticks may contain about 34 wt % to about 36 wt % of nickel, about 12 wt % to about 15 wt % of chromium, and iron with respect to a total weight thereof. According to some example embodiments, each of the support sticks may further contain 10 wt % or less of at least one of manganese, cobalt, tungsten, or silicon with respect to the total weight thereof.

According to some example embodiments, the mask frame may include first insides and second insides. According to some example embodiments, the first insides may be defined in a first direction. According to some example embodiments, the second insides may be defined in a second direction. According to some example embodiments, the support sticks may include first support sticks contacting the second insides and second support sticks spaced apart from the first support sticks.

According to some example embodiments, the protrusion patterns may be defined at the first side surface or the second side surface of the first support sticks. According to some example embodiments, the protrusion patterns may be defined at the first side surface or the second side surface of the second support sticks. According to some example embodiments t, the protrusion patterns defined at the first side surface and the protrusion patterns defined at the second side surface may have shapes that are symmetrical to each other.

According to some example embodiments, a pattern part in which a plurality of pattern holes constantly arranged at predetermined intervals are defined may be located on the active area of the mask.

According to some example embodiments, the number of pattern holes may be equal to or greater than 640,000 per square inch of the mask.

### BRIEF DESCRIPTION OF THE FIGURES

The accompanying drawings are included to provide a further understanding of the inventive concept, and are incorporated in and constitute a part of this specification. The drawings illustrate aspects of some example embodiments of the inventive concept and, together with the description, serve to explain principles of the inventive concept. In the drawings:

FIG. 1 is an exploded perspective view of a mask assembly and a substrate according to some example embodiments of the inventive concept;

FIG. 2 is an enlarged view of an area AA of FIG. 1;

FIG. 3 is an equivalent circuit view illustrating a portion of a display area according to some example embodiments of the inventive concept;

FIGS. 4A and 4B are cross-sectional view illustrating portions of the display area according to some example embodiments of the inventive concept, respectively;

FIG. 5 is an exploded perspective view of a mask frame and support sticks according to some example embodiments of the inventive concept;

FIG. 6 is an enlarged perspective view of the support stick of FIG. 5;

FIGS. 7A and 7B are cross-sectional views of a mask assembly and a magnetic plate according to some example embodiments of the inventive concept;

FIG. 8 is an exploded perspective view of a mask assembly and a substrate according to some example embodiments of the inventive concept;

FIG. 9A is an enlarged perspective view of a first support stick of FIG. 8; and

FIG. 9B is an enlarged perspective view of a second support stick of FIG. 8.

### DETAILED DESCRIPTION

In this specification, it will also be understood that when one component (or region, layer, portion) is referred to as being ‘on’, ‘connected to’, or ‘coupled to’ another component, it can be directly positioned/connected/coupled on/to the one component, or an intervening third component may also be present.

Like reference numerals refer to like elements throughout. Also, in the figures, the thickness, ratio, and dimensions of components are exaggerated for clarity of illustration.

It will be understood that although the terms such as ‘first’ and ‘second’ are used herein to describe various elements, these elements should not be limited by these terms. The terms are only used to distinguish one component from other components. For example, a first element referred to as a first element in one embodiment can be referred to as a second element in another embodiment without departing from the scope of the appended claims. The terms of a singular form may include plural forms unless referred to the contrary.

Also, “under”, “below”, “above’, “upper”, and the like are used for explaining relation association of components illustrated in the drawings. The terms may be a relative concept and described based on directions expressed in the drawings.

Unless otherwise defined, all terms (including technical and scientific terms) used herein have the same meaning as commonly understood by a person of ordinary skill in the art to which this invention belongs. Also, terms such as defined terms in commonly used dictionaries are to be interpreted as having meanings consistent with meaning in the context of the relevant art and are expressly defined herein unless interpreted in an ideal or overly formal sense.

The meaning of ‘include’ or ‘comprise’ specifies a property, a fixed number, a step, an operation, an element, a component or a combination thereof, but does not exclude other properties, fixed numbers, steps, operations, elements, components or combinations thereof.

Hereinafter, aspects of some example embodiments of the inventive concept will be described with reference to the accompanying drawings.

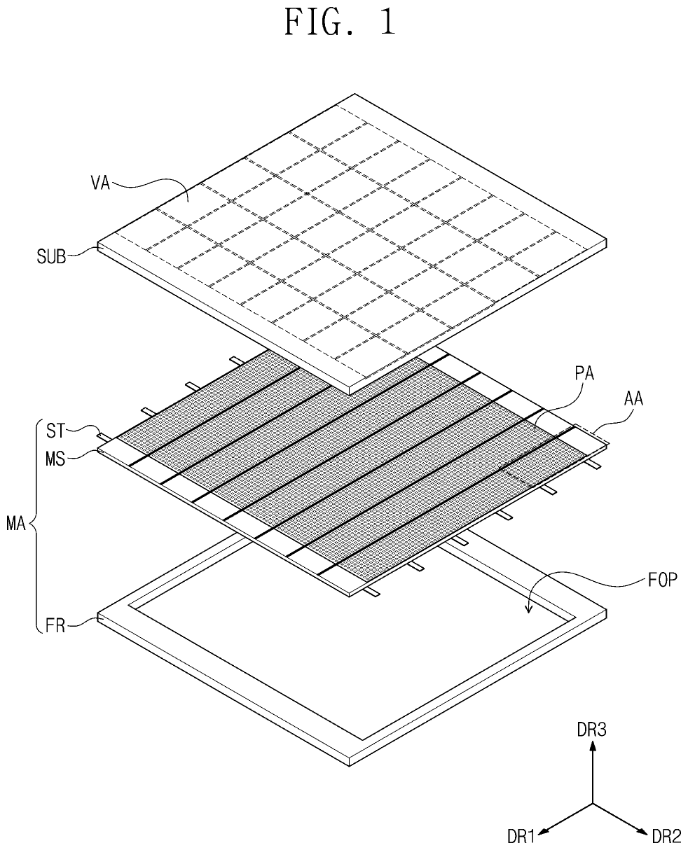

FIG. 1 is an exploded perspective view of a mask assembly MA and a substrate SUB according to some example embodiments of the inventive concept.

Referring to FIG. 1, the mask assembly MA according to some example embodiments of the inventive concept may include a mask MS, a support stick ST, and a mask frame FR. The substrate SUB may be located on the mask assembly MA.

A top surface of each component is parallel to a surface defined by a first directional axis DR1 and a second directional axis DR2. Referring to FIG. 1, a thickness direction of each component is indicated as a third directional axis DR3. An upper side (or an upper portion) and a lower side (or a lower portion) of each component is divided by the third direction axis DR3. However, directions indicated as the first to third directional axes DR1, DR2, and DR3 may be a relative concept and thus changed into different directions. Hereinafter, the first to third directions DR1, DR2, and DR3 may be directions indicated by the first to third directional axes DR1, DR2, and DR3 and designated by the same reference numerals, respectively.

In this specification, “on the plane” may means when a display device DD is viewed in the third direction DR3 (i.e., the thickness direction).

The mask assembly MA may be used for forming a plurality of thin film patterns provided in the display device DD on the substrate SUB. For example, the mask assembly MA may be used for forming a light emitting layer of an organic electroluminescence display device on the substrate SUB. The mask assembly MA may include a mask MS for forming the plurality of thin film patterns on the substrate SUB, a support stick ST supporting the mask MS to prevent the mask MS from drooping, and a mask frame FR fixing the support stick ST to the mask MS.

An opening OP may be defined in the mask frame FR. The mask frame FR may be located below the support stick ST to support the mask MS and the support stick ST. The support stick ST and the mask MS may be sequentially arranged on the mask frame FR.

The mask frame FR may be made of a metal. For example, the mask frame FR may be made of a material having small deformation when being welded to be easily coupled to the mask MS, for example, a metal having high rigidity. According to some example embodiments, a welding part at which the mask frame FR and the mask MS are coupled to each other through welding may be located on the mask frame FR. Because heat is generated around the welding part, the mask frame FR may be made of a material having small thermal deformation.

The opening FOP may expose the substrate SUB that is an object to be deposited. Because the opening FOP may have an area corresponding to a plurality of deposition areas VA on the substrate SUB, a deposition material may pass through the opening FOP during a deposition process.

The support stick ST may include a short side extending in the first direction DR1 and a long side extending in the second direction DR2 crossing the first direction DR1. The support stick ST may be located between the mask MS and the mask frame FR. The support stick ST may be arranged to cross the mask MS. Also, when the support stick ST is provided in plurality, the plurality of support sticks ST may be arranged to respectively cross the plurality of masks MS and be arranged to be spaced apart from each other in the first direction DR1. The support sticks ST adjacent to each other may have the same spaced distance therebetween.

Both ends having the shot sides of the support stick ST may extend in the second direction DR2 to protrude to the outside of the mask frame FR. Both the protruding ends may be fixed by a clamp that is provided from the outside. The support stick ST will be described below in more detail.

The mask MS may have a long side extending in the first direction DR1 and a short side extending in the second direction DR2 crossing the first direction DR1. The mask MS may be a stick type mask that is provided in plurality so as to be arranged to be spaced apart from each other in the second direction DR2. The masks MS adjacent to each other may have the same spaced distance therebetween.

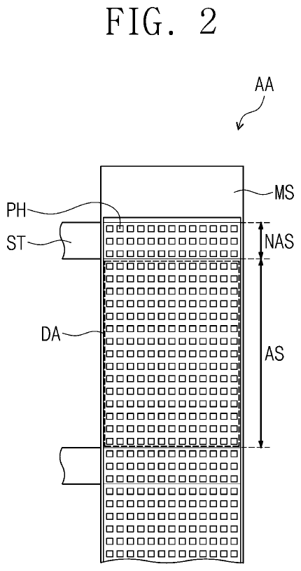

A plurality of pattern holes PH passing through the mask MS in the third direction DR3 (the thickness direction) may be defined in each of the masks MS. The pattern holes PH may be arranged to be constantly spaced at an interval (e.g., a predetermined interval) from each other. The pattern holes PH may also be defined in an active area AS (see FIG. 2) of the mask MS. The mask MS may expose an area to be deposited through the plurality of pattern holes PH to a deposition material. The provided deposition material may be deposited on the substrate SUB located above the mask MS.

About 640,000 (horizontal direction×vertical direction=800×800) or more pattern holes PH per square inch (inch²) may be defined in the mask MS. That is, about 800 or more pattern holes PH may be defined in each of the horizontal and vertical directions per inch of the mask MS. When the deposition material is deposited by using the mask MS, a high-resolution display device having a pixel density of about 800 ppi (pixel per inch) or more may be manufactured.

The plurality of pattern holes PH may be formed through an etching process. A photoresist layer having the same pattern as the plurality of pattern holes PH may be formed on a thin plate by using photoresist to form the plurality of pattern holes PH. Alternatively, a film having a shape corresponding to the plurality of pattern holes PH may be attached to a thin plate, and then, the thin plate may be etched to form the plurality of pattern holes PH. However, the embodiments of the inventive concept are not limited thereto. For example, the mask MS may be manufactured through electro-forming or electroless plating.

The mask MS may contain a metal having magnetic properties. For example, the mask may contain contents from about 63 wt % to about 65 w % of iron and about 35 wt % to about 37 wt % of nickel. The mask MS may contain invar. In this specification, the invar means invar 36 (about 36 wt % of nickel and about 64 wt % of iron).

Hereinafter, although the substrate SUB is located above the mask assembly MA, the embodiments of the inventive concept are not limited thereto. For example, the substrate SUB may be located below the mask assembly MA.

The substrate SUB may include a plurality of deposition areas VA. The deposition areas VA may be arranged in the form of a matrix in the first direction DR1 and the second direction DR2. The deposition areas VA may be areas that are exposed to the deposition material by the mask MS when the deposition material is provided. Although each of the deposition areas VA has a rectangular shape, the embodiments of the inventive concept are not limited thereto. For example, the embodiments of the inventive concept re not specifically limited to the shape of each of the deposition areas VA. For example, each of the deposition areas VA may have square, polygonal, amorphous, spherical, hemispherical, elliptical, or semi-elliptical shape.

Referring to FIGS. 1 and 2, the mask MS may include a non-active area NAS overlapping the support stick ST on a plane and an active area AS that is a portion except for the non-active area NAS. The active area AS may be an area through which the deposition material is transmitted through the pattern holes PH, and the non-active area NAS may be an area by which the deposition material is blocked because the area is covered by the support stick ST.

When the deposition material is deposited on the substrate SUB, the plurality of deposition areas VA may be in a state in which other components are already located on the deposition areas VA. For example, the plurality of deposition areas VA may be in a state in which thin films such as a transistor and a capacitor are located on the deposition areas VA.

The deposition material may be deposited on the plurality of deposition areas VA defined on the substrate SUB to manufacture a display device for displaying an image. The display device may include a display area DA on which images are displayed. As illustrated in FIG. 2, the display area DA may be an area corresponding to the active area AS of the mask MS. The display area may be an area overlapping the deposition area VA on the plane.

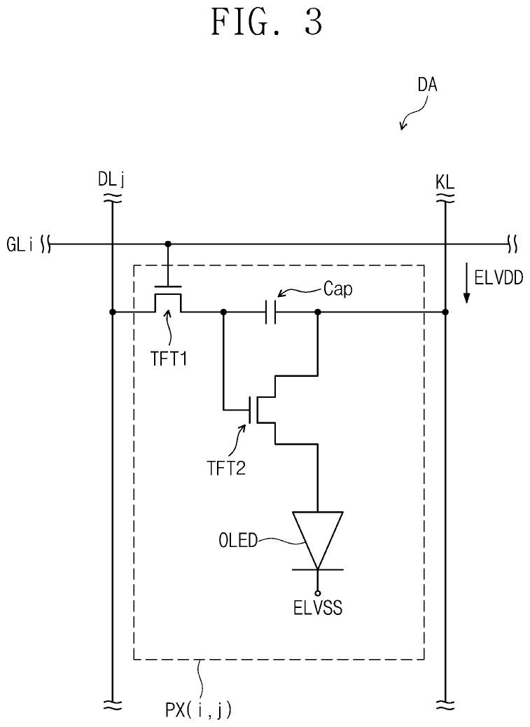

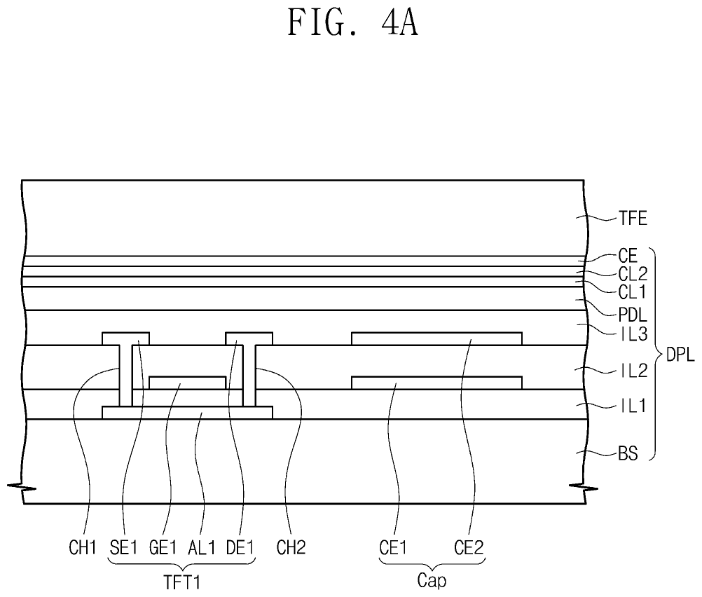

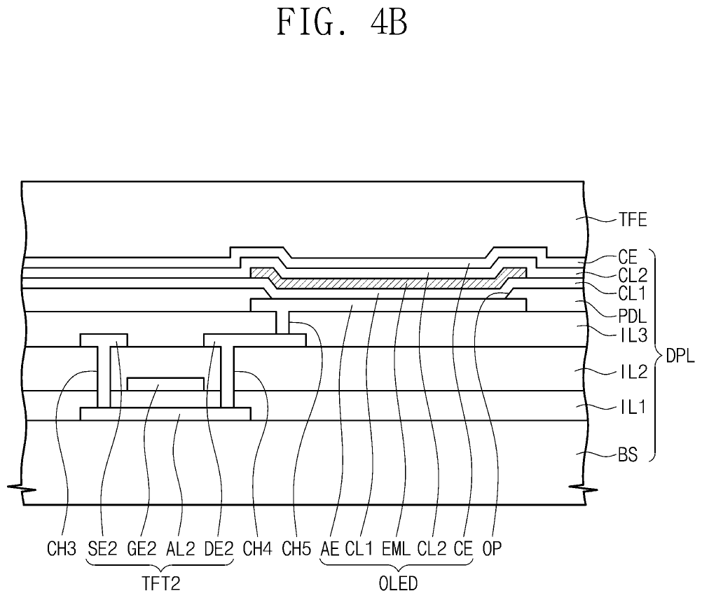

Hereinafter, the display area DA will be described in detail with reference to FIGS. 3, 4A, and 4B.

FIG. 3 is an equivalent circuit view illustrating a portion of the display area DA according to some example embodiments of the inventive concept.

FIGS. 4A and 4B are cross-sectional view illustrating portions of the display area DA according to some example embodiments of the inventive concept, respectively.

The display area DA may be an area corresponding to each of the deposition areas VA. The deposition material may be deposited on the substrate SUB to manufacture the display device, and the manufactured display device may include the display area DA on which an image is displayed.

The display area DA according to some example embodiments of the inventive concept may include a plurality of pixels. The pattern hole PH defined in the active area AS may correspond to one pixel of the display area DA. FIG. 3 illustrates an example of a signal diagram of one pixel PX(i,j) of the plurality of pixels, and FIGS. 4A and 4B illustrate cross-sectional views of the display area DA on which the one pixel PX(i,j) is located.

The pixel PX(i,j) receives a gate signal from an i-th gate line GLi and receives a data signal from a j-th data line DLj. Also, the pixel PX(i,j) receives a first power source voltage ELVDD from a power line KL. The pixel PX(i.j) includes a first thin film element TFT1, a second thin film element TFT2, a capacitor Cap, and an organic light emitting element OLED.

The first thin film element TFT1 outputs the data signal applied to the j-th data line DLj in response to the gate signal applied to the i-th gate line GLi. The capacitor Cap charges a voltage corresponding to the data signal received from the first thin film element TFT1.

The second thin film element TFT2 is connected to the organic light emitting element OLED. The second thin film element TFT2 controls driving current flowing through the organic light emitting element OLED to correspond to a charge amount stored in the capacitor Cap.

The organic light emitting element OLED includes a first electrode connected to the second thin film element TFT2 and a second electrode receiving a second power source voltage ELVSS. The second power source voltage ELVSS has a level less than that of the first power source voltage ELVDD.

Also, the organic light emitting element OLED includes an organic light emitting layer located between at least the first and second electrodes. The organic light emitting element OLED emits light during a turn-on period of the second thin film element TFT2.

The pixel PX(i,j) may have various configurations according to various embodiments, but is not limited to a specific embodiment.

Referring to FIGS. 4A and 4B, a display layer DPL includes a base layer BS, a first thin film element TFT1, a second thin film element TFT2, a capacitor Cap, and an organic light emitting element OLED. The embodiments of the inventive concept are not specifically limited to the material of the base layer BS. For example, the base layer BS may include a glass substrate, a metal substrate, and a flexible plastic substrate.

A semiconductor pattern AL1 (hereinafter, referred to as a first semiconductor pattern) of the first thin film element TFT1, a semiconductor pattern AL2 (hereinafter, referred to as a second semiconductor pattern) of the second thin film element TFR2, and a first insulation layer IL1 are located on the base layer BS. The first insulation layer IL1 covers the first semiconductor pattern AU and the second semiconductor pattern AL2. The first electrode CE1 of the capacitor Cap may be located on the first insulation layer IL1.

A control electrode GE1 (hereinafter, referred to as a first control electrode) of the first thin film element TFT1, a second control electrode GE2 (hereinafter, referred to as a second control electrode) of the second thin film element TFT2, a second insulation layer IL2 are located on the first insulation layer IL1. The second insulation layer IL2 covers the first control electrode GE1 and the second control electrode GE2.

Each of the first insulation layer IL1 and the second insulation layer IL2 include an organic and/or inorganic layer. Each of the first insulation layer IL1 and the second insulation layer IL2 may include a plurality of thin films.

An input electrode SE1 (hereinafter, referred to as a first input electrode) and an output electrode DE1 (hereinafter, referred to as a first output electrode) of the first thin film element TFT1, an input electrode SE2 (hereinafter, referred to as a second input electrode) and an output electrode DE2 (hereinafter, referred to as a second output electrode) of the second thin film element TFT2, and a third insulation layer IL3 are located on the second insulation layer IL2.

A second electrode CE2 of the capacitor Cap may be disposed on the second insulation layer IL2. The third insulation layer IL3 covers the first input electrode SE1, the first output electrode DE1, the second input electrode SE2, the second output electrode DE2, and the second electrode CE2.

The first input electrode SE1 and the first output electrode DE1 are connected to the first semiconductor pattern AL1 through first and second through-holes CH1 and CH2, which pass through the second and third insulation layers IL2 and IL3, respectively. Similarly, the second input electrode SE2 and the second output electrode DE2 are connected to the second semiconductor pattern AL2 through third and fourth through-holes CH3 and CH4, which pass through the second insulation layer IL2 and the third insulation layer IL3, respectively.

The organic light emitting element OLED and a pixel defining layer PDL are located on the third insulation layer IL3. The pixel defining layer PDL exposes an area of the third insulation layer, which overlaps the organic light emitting element OLED. The pixel defining layer PDL substantially defines a light emitting area.

The organic light emitting element OLED includes an anode AE, a light emitting layer EML, a cathode CE, and a hole transport region(or a first common layer) CL1 defined between the cathode CE and the light emitting layer EML, and the light emitting layer AE and the anode AE are located on the third insulation layer IL3. The anode AE is provided in plurality, and the plurality of anodes AE are respectively arranged to overlap the plurality of light emitting areas. The pixel defining layer PDL is located on the anode AE to expose at least a portion of the anode AE. The anode AE is connected to the second output electrode DE2 through a fifth through-hole CH5 defined in the third insulation layer IL3.

Although the cathode CE is located on the anode AE in FIGS. 4A and 4B, this is merely an example. For example, the positions of the anode AE and the cathode CE may be changed according to a configuration of the display layer DPL.

The hole transport region 1 may be located on the anode AE to cover the anode AE and the pixel defining layer PDL. The hole transport region CL1 may include at least one of a hole injection layer, a hole transport layer, or a single layer having a hole injection function and a hole transport function.

The light emitting layer EML may be arranged on the hole transport region CL1. The light emitting layer EML is provided in plurality, and the plurality of light emitting layers EML respectively overlap the light emitting areas. The light emitting layer EML may include a fluorescent material or a phosphorescent material. The light emitting layer EML may generate light having one color or generate light in which at least two colors are mixed with each other.

The electron transport region CL2 may be located on the light emitting layer EML to cover the light emitting layer EML and the hole transport region CL1. The electron transport region CL2 may include at least one of an electron transport material or an electron injection material. The electron transport region CL2 may be an electron transport layer comprising an electron transport material or be an electron injection/transport single layer including an electron transport material and an electron injection material.

The cathode CE may be located on the electron transport region CL2 to face the anode AE. The cathode CE may be made of a material having a low work function to facilitate the electron injection.

The cathode CE and the anode AE may be made of different materials according to a light emitting type. For example, when the display area DA according to some example embodiments of the inventive concept is a top emission type, the cathode CE may be a transmissive electrode, and the anode AE may be a reflective electrode.

Alternatively, for example, the display area DA according to some example embodiments of the inventive concept is a bottom emission type, the cathode CE may be a reflective electrode, and the anode AE may be a transmissive electrode. The display area DA according to some example embodiments of the inventive concept may include organic light emitting elements having various structures and also are not limited to a specific embodiment.

A thin film encapsulation layer TFE may be located on the cathode CE. The thin film encapsulation layer TFE may cover an entire surface of the cathode CE to seal the organic light emitting element OLED.

The thin film encapsulation layer TFE may have a thickness of about 1 μm to about 10 μm. The display area DA may include the thin film encapsulation layer TFE to realize the thin display area DA.

The thin film encapsulation layer TFE may include a plurality of inorganic layers. Each of the inorganic layers may include at least one of silicon nitride or silicon oxide. Also, the thin film encapsulation layer TFE may further include a different functional layer located between the inorganic layers.

The mask assembly MA illustrated in FIG. 1 may be applied to a process of manufacturing various constituents constituting the display area DA. For example, the substrate SUB of FIG. 1 may be provided in a state in which the hole transport region CL1 is formed in each of the plurality of deposition areas VA. Thereafter, the light emitting layer EML may be formed through a mask MS. That is, the mask MS may be applied to a process of forming the light emitting layer EML. However, this is merely an example. The mask MS according to some example embodiments of the inventive concept may be applied to various processes.

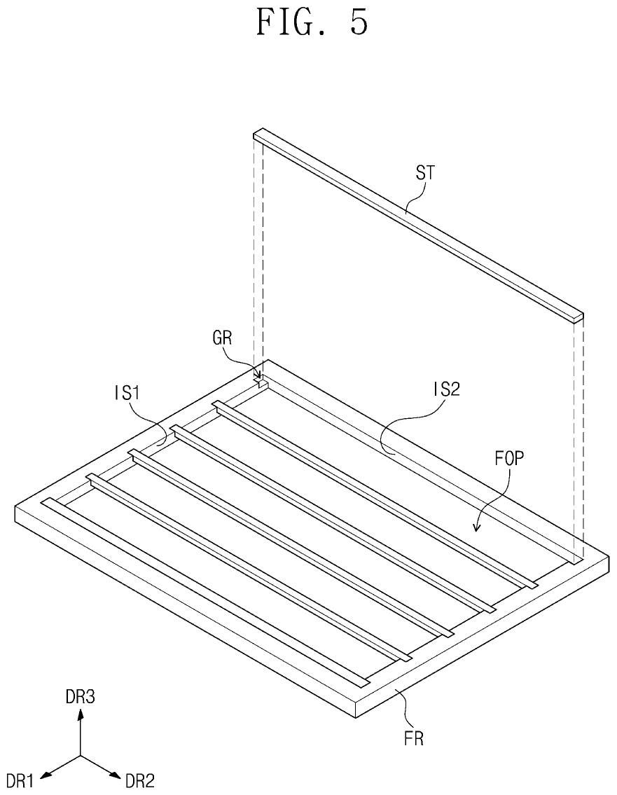

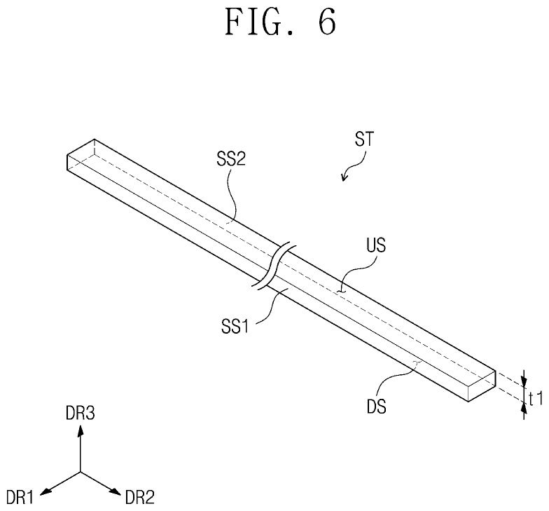

FIG. 5 is an exploded perspective view of a mask frame FR and support sticks ST according to some example embodiments of the inventive concept. FIG. 6 is an enlarged perspective view of the support stick ST of the FIG. 5.

Referring to FIG. 5, the mask frame FR may include first insides IS1 defined in the first direction DR1 and second insides IS2 defined in the second direction DR2 crossing the first direction DR1. The opening FOP may be defined by the first insides IS1 and the second insides IS2.

Coupling grooves GR may be defined in the first insides IS1. The coupling grooves GR may be provided in a pair to face each other in the second direction DR2. The plural pairs of coupling grooves GR may be arranged in the first direction DR1. The support sticks ST may be coupled to the plural pairs of coupling grooves GR, respectively. However, the coupling method of the support sticks ST is not specifically limited. For example, the support sticks ST may be coupled through various methods such as welding.

Referring to FIGS. 5 and 6, each of the support sticks ST may include a top surface US defined by a long side and a short side, a bottom surface DS facing the top surface US, a first side surface SS1 located between the top surface US and the bottom surface DS to connect the top surface US to the bottom surface DS, and a second side surface SS2 facing the first side surface SS1.

The support stick ST may contain about 34 wt % to about 36 wt % of nickel, about 12 wt % to about 15 wt % of chromium, and iron with respect to a total weight of the support stick ST. In this specification, wt % means weight percent (weight ratio). The support stick ST may be made of only nickel, chromium, and iron. Here, a ratio of iron may occupy a remaining weight ratio of the total weight of the support stick ST except for the weight ratio of nickel and the weight ratio of chromium.

For example, the support stick ST may contain elinvar containing about 36 wt % of nickel, about 12 wt % of chromium, and about 52 wt % of iron. However, this is merely an example and the embodiments of the inventive concept are not limited thereto.

The support stick ST may further contain at least one of manganese, cobalt, tungsten, or silicon in addition to nickel, chromium, and iron. The support stick ST may further contain at least one of manganese, cobalt, tungsten, or silicon in the total weight of the support stick ST. That is, even when the support stick ST contains two or more of manganese, cobalt, tungsten, or silicon, a weight of two or more atoms may be less than or equal to about 10 wt %.

A thermal expansion coefficient of the support stick ST may be equal to or less than about 10 ppm/° C. 10⁻⁶. The support stick ST may have relative permeability of about 2,000 to about 10,000. In this specification, the relative permeability means a ratio of permeability of a medium to permeability of vacuum.

Among the materials of the support stick ST, nickel may be greatly affect an increase and decrease of the thermal expansion coefficient of the support stick ST. When nickel in the total weight of the support stick ST has a content of about 34 wt % to about 36 wt %, it is easy to maintain the thermal expansion coefficient of the support stick ST to about 10 ppm/° C. 10⁻⁶ or less.

Among the materials of the support stick ST, chromium may be greatly affect an increase and decrease of the relative permeability of the support stick ST. When chromium in the total weight of the support stick ST has a content of about 12 wt % to about 15 wt %, it is easy to maintain the relative permeability of the support stick ST to about 2,000 to about 10,000.

The support stick ST may be adjusted in thermal expansion coefficient and relative permeability. Also, the support stick ST may contain at least one of manganese, cobalt, tungsten, or silicon to adjust characteristics such as strength of the support stick ST. When at least one of manganese, cobalt, tungsten, or silicon is contained at a content of about 10 wt % or more, the thermal expansion coefficient or permeability may deviate from the above-described ranges.

In general, the support stick ST according to some example embodiments may have a thermal expansion coefficient of about 1.2 ppm/° C. 10⁻⁶ or less. However, the embodiments of the inventive concept are not limited thereto. For example, the lower limit of the thermal expansion coefficient of the support stick ST is not specifically limited.

Because the support stick ST is exposed to high-temperature heat in the deposition process, when the thermal expansion coefficient of the support stick ST exceeds about 10 ppm/° C. 10⁻⁶, the support stick ST may be largely expanded or deformed during the deposition. When the support stick ST is expanded or deformed, the arrangement of the masks MS arranged on the support stick ST may be warped. Even if the arrangement of the masks MS is slightly warped, a shadow effect may occur. Thus, the deposition may not precisely occur.

For example, when a high-resolution display device having a pixel density of about 800 ppi or more is manufactured, because 640,000 pixels or more per square inch of the mask MS have to be densely formed. Thus, the mask MS has to be manufactured thinner about ⅔ than the existing mask MS to prevent the shadow effect from occurring. As a result, the influence of the mask MS due to the deformation of the support stick ST further increases. Also, in the case of the high resolution, because the masks MS are densely formed on the masks MS, even if the arrangement is slightly warped, the shadow effect significantly increase.

Because the support stick ST according to some example embodiments has a thermal expansion coefficient less than about 10 ppm/° C. 10⁻⁶, even though the support stick ST is exposed at a high temperature during the deposition, the expansion or deformation of the support stick ST may be reduced. Thus, the deposition material may be precisely deposited on the substrate SUB without the above-described limitations.

The thermal expansion coefficient according to some example embodiments may be measured through following methods. In this specification, um means micro meter.

The thermal expansion coefficient CTE is measured by using TMA(Q400) of TA instrument company. The manufactured support stick ST is sampled at a size of about 100 um×100 um or 50 um×50 um and stabilized by a load of about 0.05 N under a nitrogen atmosphere, and then, a variation in length of a film of the sampled support stick ST is measured. The thermal expansion coefficient is evaluated by measuring a degree of expansion of the film of the sampled support stick ST in a longitudinal direction, i.e., on the plane. After cooling the sampled support stick ST at a temperature of about 0° C., the sampled support stick ST is heated at a temperature of about 120° C. at a speed of about 5° C./min to minimize the influence of factors such as moisture or dust. The above-described measurement process is repeatedly performed three times to measure the thermal expansion coefficient within a temperature range of about 0° C. to about 120° C.

The support stick ST may have a thickness t1 of about 50 um to about 150 um. Detailed descriptions will be described later.

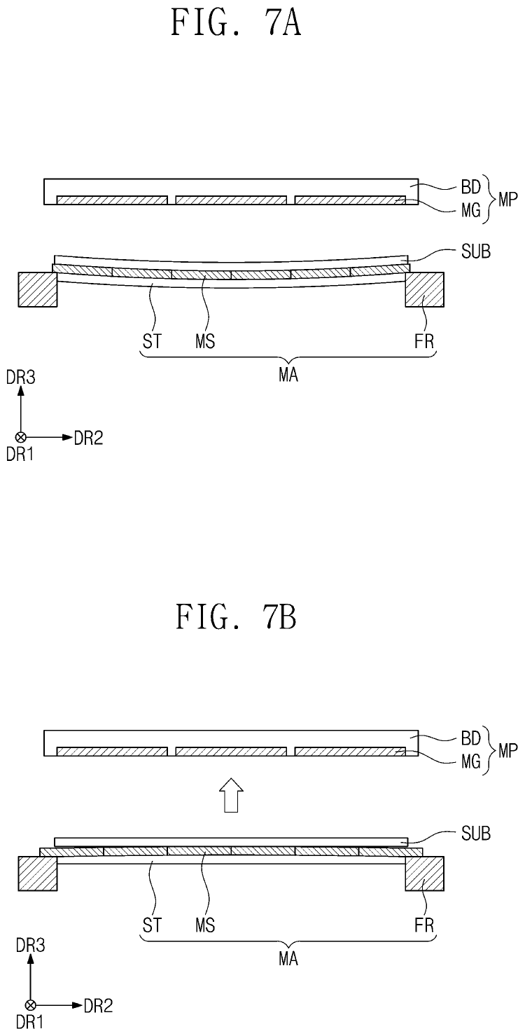

FIGS. 7A and 7B are cross-sectional views of the mask assembly MA and a magnetic plate MP according to some example embodiments of the inventive concept. Referring to FIGS. 7A and 7B, the magnetic plate MP may be further located on the mask assembly MA according to some example embodiments.

The magnetic plate MP generates magnetism. The magnetic plate MP may include a magnetic member MG and a body part BD. The body part BD may accommodate the magnetic member MG and have a plate shape. According to some example embodiments, when the magnetic member MG has the plate shape, the body part BD may be omitted.

Although the magnetic member MG is provided in plurality to be spaced apart from each other in some example embodiments, the arrangement and number of magnetic member MG according to some example embodiments are not specifically limited thereto. The configuration of the magnetic plate MG of FIGS. 7A and 7B is merely an example and thus is not specifically limited as long as the magnetic plate generates the magnetism.

Referring to FIG. 7A, when the magnetism is not generated in the magnetic plate MP, the support sticks ST and the masks MS may droop downward. Referring to FIG. 7B, when the magnetism is generated in the magnetic plate MP, attractive force is generated between the magnetic plate MP and the mask MA. Thus, the downward drooping of the support sticks ST and the masks MS due to gravity may be prevented or reduced. Although the magnetic member MG is provided as an electromagnet in FIGS. 7A and 7B, the embodiments of the inventive concept are not limited thereto. For example, the magnetic member MG may be provided as a permanent magnet.

When the support stick ST has relative permeability of about 2,000 or less, because the influence of the support stick ST due to the magnetism is less, the support stick ST may droop downward even though the magnetism is generated in the magnetic plate MP. Thus, the arrangement of the masks MS may be warped.

When the relative permeability of the support stick ST exceeds about 10,000, because the influence of the support stick ST due to the magnetism is large, the support stick ST may be bent toward the magnetic plate MP by the magnetism generated in the magnetic plate MP. Thus, the arrangement of the masks MS may be warped. As described above, when the masks MS are provided as masks for manufacturing the high-resolution display device having the pixel density of about 800 ppi or more, the masks may be largely affected by the warpage and drooping of the support stick ST.

Because the support stick ST according to some example embodiments has the relative permeability of about 2,000 to about 10,000, the support plate ST may be prevented from being bent or drooping downward toward the magnetic plate MP by the magnetism generated in the magnetic plate MP. Thus, the deposition material may be precisely deposited on the substrate SUB.

The relative permeability of the support stick ST may be about 0.5 times of that of the mask MS. When the relative permeability of the support stick ST is about 0.5 times or less of that of the mask MS, even though the magnetism is generated in the magnetic plate, the mask MS may not be affected by the support stick MS.

The support stick ST may have a thickness t1 (see FIG. 6) of about 50 um to about 150 um or about 50 um to about 100 um in the third direction DR3 perpendicular to the plane defined in the first direction DR1 and the second direction DR2. When the support stick ST has a thickness t1 of about 50 um or less, the mask MS may not be supported to droop downward. Also, the support stick ST may be bent toward the magnetic plate MP by the magnetism generated in the magnetic plate MP.

When the support stick ST has a thickness t1 of about 150 um or more, the support stick ST may drooping downward by the gravity. Thus, the support stick ST may be deformed.

According to some example embodiments, because the support stick ST has a thickness t1 of about 50 um to about 150 um, the support stick ST may not be deformed while sufficiently supporting the masks MS.

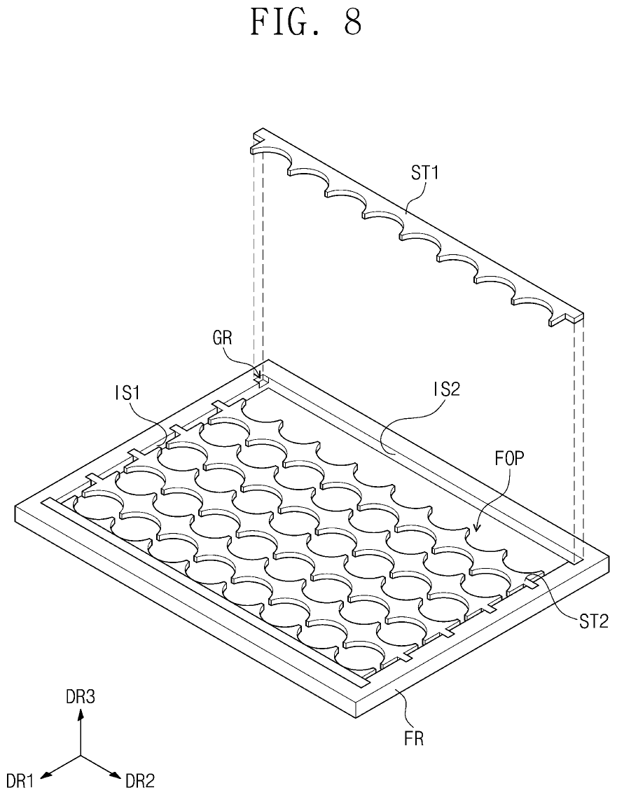

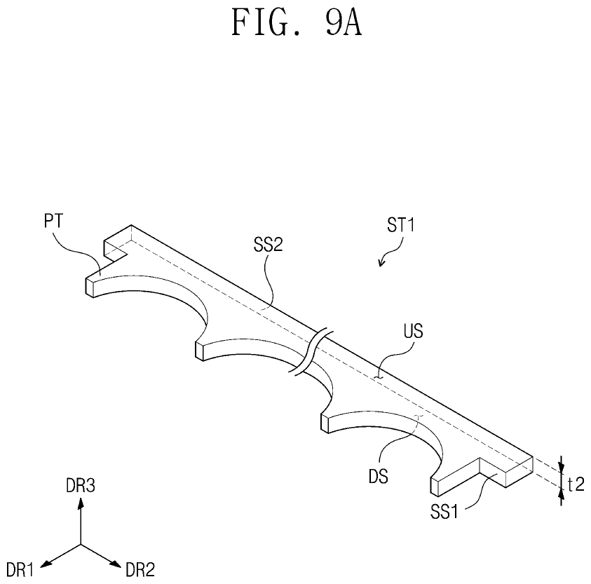

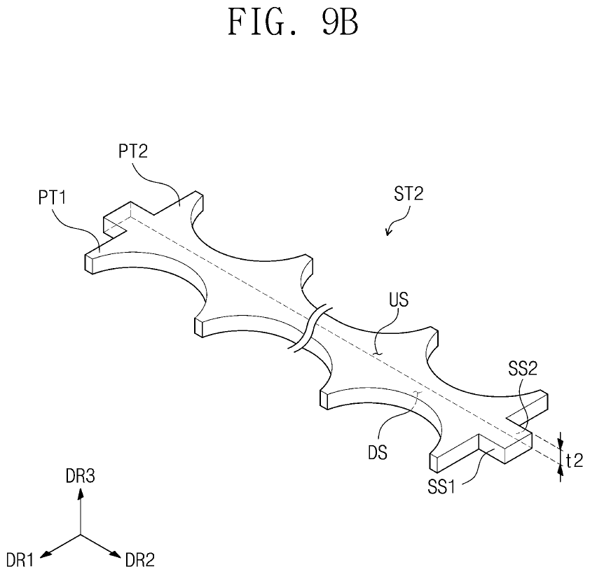

FIG. 8 is an exploded perspective view of the mask assembly MA and the substrate SUB according to some example embodiments of the inventive concept. FIG. 9A is an enlarged perspective view of a first support stick ST1 of FIG. 8. FIG. 9B is an enlarged perspective view of a second support stick ST2 of FIG. 8.

If separate explanation is not provided, substantially the same description as that of each of the above-described support sticks ST may be applied to the first support stick ST1 and the second support sticks ST2. Thus, hereinafter, some duplicated description may be omitted or briefly explained.

A plurality of protrusion patterns PT overlapping the non-active area NAS on the plane and protruding from a first side surface SS1 or a second side surface SS2 may be defined on at least one of the first side surface SS1 or the second side surface SS2 of the support sticks ST. The protrusion patterns PT may extend from the first side surface SS1 and the second side surface SS2. The protrusion patterns PT may be integrated with the support sticks ST. The protrusion patterns PT may include the same material as the support sticks ST.

The protrusion patterns PT may include first protrusion patterns PT1 protruding from the first side surface SS1 and second protrusion patterns PT2 protruding from the second side surface SS2.

The support stick ST on which the protrusion pattern PT is located on one of the first side surface SS1 and the second side surface SS2 may be called a first support stick ST1. The support stick ST on which the protrusion pattern PT is located on all the first side surface SS1 and the second side surface SS2 may be called a second support stick ST2. That is, the support stick ST including one of the first protrusion pattern PT1 and the second protrusion pattern PT2 may be defined as the first support stick ST1, and the support stick ST including all the first protrusion pattern PT1 and the second protrusion pattern PT2 may be defined as the second support stick ST2.

The first support sticks ST1 may contact second insides IS2 of the mask frame. The second support sticks ST2 may be spaced apart from the first sticks ST1. Openings may be defined between the first support stick ST1 and the second support stick ST2 and between the second support stick ST2 and the second support stick ST2, respectively.

In the second support stick ST2, the protrusion pattern PT defined on the first side surface SS1 and the protrusion pattern PT defined on the second side surface SS2 may one-to-one correspond to each other. The protrusion pattern PT defined on the first side surface SS1 and the protrusion pattern PT defined on the second side surface SS2 may be symmetrical to each other. The protrusion pattern PT may overlap the non-active area NAS (see FIG. 2) of the mask MS on the plane to define the active area SA (see FIG. 2) of the mask MS.

When the display area DA (see FIG. 2) having a rectangular or square shape is formed, the protrusion pattern PT may be omitted as illustrated in FIGS. 5 and 6.

Because the deposition area VA of the substrate SUB (see FIG. 1) is defined as an area that does not overlap the support stick ST, the pattern may be formed on the support stick ST to adjust a shape of the deposition area VA of the substrate SUB. When the first and second support sticks ST1 and ST2 include the protrusion pattern PT, the display area DA (see FIG. 2) having the shape of the opening defined by the shape of the protrusion pattern ST may be formed.

For example, the protrusion patterns PT may have shapes having curved portions and spaced apart from each other. In this case, the protrusion patterns may be provided for forming a display device for wearable glasses.

Although the protrusion patterns PT adjacent to each other are spaced apart from each other in FIGS. 8, 9A, and 9B, the embodiments of the inventive concept are not limited thereto. For example, a portion of the protrusion pattern PT, which is farthest from the first side surface SS1 or the second side surface SS2, may contact a portion of the protrusion pattern PT of the other adjacent first or second support sticks ST1 and ST2, which is farthest from the first side surface SS1 or the second side surface SS2. Also, although the protrusion pattern has a plurality of semi-elliptic curves and a straight line connecting the semi-elliptic curves to each other, the protrusion pattern PT may have only the semi-elliptic curves.

Furthermore, the protrusion pattern PT may be variously deformed according to the shape of the display area DA (see FIG. 2) to be formed on the substrate SUB. For example, the shape of the protruding pattern PT may be correspondingly modified according to various shapes of the display area DA (see FIG. 2) such as an amorphous, polygonal, spherical, hemispherical, oval, or semi-elliptical shape.

Because the protrusion pattern PT is defined to correspond to the shape of the display area DA (see FIG. 2), each of the first and second support sticks ST1 and ST2 may have a surface area greater than that of the support stick ST (see FIG. 5) on which the protrusion patterns are not located. Thus, the first and seconds support sticks ST1 and ST2 may more well support the masks MS (see FIG. 1).

Each of the first and second support sticks ST1 and ST2 may have a surface greater than that of the support stick ST (see FIG. 5) and thus more easily droop downward due to the gravity. To prevent this limitation from occurring, each of the first and second support sticks ST1 and ST2 may have a thickness t2 that is less than that of the support stick ST (see FIG. 5) in the third direction DR3. For example, each of the first and second support sticks ST1 and ST2 may have a thickness of 50 um to about 100 um. When each of the first and second support sticks ST1 and ST2 has a thickness t2 of about 100 um or more, the first and second support sticks ST1 and ST2 may droop downward due to the gravity, and thus, the support stick ST may be deformed.

When each of the first and second support sticks ST1 and ST2 has a thickness t1 of about 50 um or less, the mask MS may not be sufficiently supported to droop downward. Also, each of the support sticks ST1 and ST2 may be bent toward the magnetic plate MP by the magnetism generated in the magnetic plate MP.

When each of the first and second support sticks ST1 and ST2 is bent toward the magnetic plate PT, the mask MS (see FIG. 1) may be more largely affected by the wide surface area of each of the first and second sticks ST1 and ST2. Thus, the arrangement of the masks MS may be warped more largely than that described with reference to the support stick ST.

Each of the first and second support sticks ST1 and ST2 according to some example embodiments may have the relative permeability within the above-described thickness range of about 2,000 to about 10,000 to prevent the above-described limitation from occurring.

Because each of the first and second support sticks ST1 and ST2 has a surface area greater than that of the support stick ST (see FIG. 5), each of the first and second support sticks ST1 and ST2 may be more expanded or deformed by the high-temperature heat applied during the deposition. Thus, the support sticks ST1 and ST2, each of which has the relatively narrow surface area, may be warped more largely than the warped degree of the masks MS (see FIG. 1) due to the thermal expansion.

However, because each of the first and second support sticks ST1 and ST2 according to some example embodiments has the thermal expansion coefficient of about 10 ppm/° C. 10⁻⁶ or less, the above-described limitation may not occur.

The support stick ST according to some example embodiments may contain about 34 wt % to about 36 wt % of nickel, about 12 wt % to about 15 wt % of chromium, and iron.

The support stick ST according to some example embodiments may have a thermal expansion coefficient of about 1.2 ppm/° C. 10⁻⁶ to about 10 ppm/° C. 10⁻⁶ and relative permeability of about 2,000 to about 10,000.

The pattern may be located on at least one of the first side surface or the second side surface of the support stick ST according to some example embodiments.

When the deposition material is deposited by using the mask assembly MA including the support stick ST according to some example embodiments, the deposition material may be precisely deposited.

The mask assembly according to some example embodiments may precisely deposit the deposition material.

It will be apparent to those skilled in the art that various modifications and variations can be made in the inventive concept. Thus, it is intended that the present disclosure covers the modifications and variations of this invention provided they come within the scope of the appended claims and their equivalents. Thus, to the maximum extent allowed by law, the scope of the present invention is to be determined by the broadest permissible interpretation of the following claims and their equivalents, and shall not be restricted or limited by the foregoing detailed description.

What is claimed is:

1. A mask assembly comprising:
a mask frame in which an opening is defined;
a mask on the mask frame; and
a support stick between the mask frame and the mask, the support stick comprising a short side extending in a first direction and a long side extending in a second direction crossing the first direction,
wherein the mask has a non-active area overlapping the support stick on a plane and an active area different from the non-active area, and
the support stick contains 34 wt % to 36 wt % of nickel, 12 wt % to 15 wt % of chromium, and iron with respect to a total weight thereof.

2. The mask assembly of claim 1, wherein the support stick further contains 10 wt % or less of at least one of manganese, cobalt, tungsten, or silicon with respect to the total weight thereof.

3. The mask assembly of claim 1, wherein the support stick has a thermal expansion coefficient of 10 ppm/° C. 10⁻⁶ or less.

4. The mask assembly of claim 1, wherein the support stick has relative permeability of 2,000 to 10,000.

5. The mask assembly of claim 1, wherein the support stick has a thickness of 50 um to 150 um in a third direction perpendicular to a plane defined by the first direction and the second direction.

6. The mask assembly of claim 1, wherein the mask comprises invar.

7. The mask assembly of claim 1, wherein the support stick has a relative permeability that is 0.5 times of that of the mask.

8. The mask assembly of claim 1, wherein a plurality of pattern holes constantly arranged at intervals are defined in the active area of the mask.

9. The mask assembly of claim 8, wherein a number of the pattern holes is equal to or greater than 640,000 per square inch of the mask.

10. The mask assembly of claim 1, wherein the support stick comprises:
a top surface defined by the long side and the short side;
a bottom surface facing the top surface;
a first side surface between the top surface and the bottom surface to connect the top surface to the bottom surface; and
a second side surface facing the first side surface,
wherein at least one of the first side surface or the second side surface overlaps the non-active area on the plane, and a plurality of protrusion patterns protruding from the first side surface or the second side surface are defined on at least one of the first side surface or the second side surface.

11. The mask assembly of claim 10, wherein the protrusion patterns extend from the first side surface and the second side surface.

12. The mask assembly of claim 10, wherein the protrusion patterns comprise first protrusion patterns protruding from the first side surface and second protrusion patterns protruding from the second side surface, and
the first protrusion patterns and the second protrusion patterns one-to-one correspond to each other.

13. The mask assembly of claim 1, further comprising a magnetic plate disposed on the mask to generate magnetism.

14. A mask assembly comprising:
a mask frame in which an opening is defined;
a plurality of support sticks on the mask frame, spaced apart from each other in a first direction, and comprising a long side and a short side;
a plurality of masks on the support sticks,
wherein each of the masks has a non-active area overlapping the support stick on a plane and an active area that is an area except for the non-active area,
each of the support sticks comprises:
a top surface defined by the long side and the short side;
a bottom surface facing the top surface;
a first side surface between the top surface and the bottom surface to connect the top surface to the bottom surface; and
a second side surface facing the first side surface,
at least one of the first side surface or the second side surface overlaps the non-active area on the plane, and a plurality of protrusion patterns protruding from the first side surface or the second side surface are defined on at least one of the first side surface or the second side surface,
the support sticks has a thermal expansion coefficient of about 10 ppm/° C. 10⁻⁶ or less, and
the support stick has relative permeability that is about 0.5 times of that of the mask.

15. The mask assembly of claim 14, wherein each of the support sticks has relative permeability of about 2,000 to about 10,000.

16. The mask assembly of claim 14, wherein each of the support sticks contains 34 wt % to 36 wt % of nickel, 12 wt % to 15 wt % of chromium, and iron with respect to a total weight thereof.

17. The mask assembly of claim 16, wherein each of the support sticks further contains 10 wt % or less of at least one of manganese, cobalt, tungsten, or silicon with respect to the total weight thereof.

18. The mask assembly of claim 14, wherein the mask frame comprises first insides defined in a first direction and second insides defined in a second direction,
the support sticks comprise first support sticks contacting the second insides and second support sticks spaced apart from the first support sticks,
the protrusion patterns are defined at the first side surface or the second side surface of the first support sticks, and
the protrusion patterns are defined at the first side surface and the second side surface of the second support sticks.

19. The mask assembly of claim 14, wherein the protrusion patterns defined at the first side surface and the protrusion patterns defined at the second side surface have shapes that are symmetrical to each other.

20. The mask assembly of claim 14, wherein a plurality of pattern holes constantly arranged at intervals are defined in the active area of the masks, and
a number of the pattern holes is equal to or greater than 640,000 per square inch of the masks.
